(19) United States
(12) Patent Application Publication
(10) Pub. No.: US 2011/0227102 A1
(43) Pub. Date: Sep. 22, 2011

(54) HIGH EFFICACY LED LAMP WITH REMOTE PHOSPHOR AND DIFFUSER CONFIGURATION

(75) Inventors: Christopher P. Hussell, Cary, NC (US); Ronan Letoquin, Fremont, CA (US)

(73) Assignee: CREE, Inc.

(21) Appl. No.: 13/029,063

(22) Filed: Feb. 16, 2011

Related U.S. Application Data
(63) Continuation-in-part of application No. 12/848,825, filed on Aug. 2, 2010.
Application No. 12/848,825 is a continuation-in-part of application No. 12/889,719, filed on Sep. 24, 2010.
Application No. 12/889,719 is a continuation-in-part of application No. 12/975,820, filed on Dec. 22, 2010.
(60) Provisional application No. 61/339,516, filed on Mar. 3, 2010.
(60) Provisional application No. 61/339,515, filed on Mar. 3, 2010.
(60) Provisional application No. 61/386,437, filed on Sep. 24, 2010.
(60) Provisional application No. 61/424,665, filed on Dec. 19, 2010.
(60) Provisional application No. 61/424,670, filed on Dec. 19, 2010.
(60) Provisional application No. 61/434,355, filed on Jan. 19, 2011.
(60) Provisional application No. 61/435,326, filed on Jan. 23, 2011.
(60) Provisional application No. 61/435,759, filed on Jan. 24, 2011.

(51) Int. Cl. H01L 33/58

(52) U.S. Cl. 257/89; 257/98; 257/E33.06

(57) ABSTRACT

Solid state lamps and bulbs comprising different combinations and arrangements of a light source, wavelength conversion elements with one or more distinct phosphor layers or regions which are positioned separately or remotely with respect to the light source, and a diffuser element are provided. These elements may be arranged on or in conjunction with a thermal management device that allows for the fabrication of lamps and bulbs that are efficient, reliable and cost effective and can provide an essentially omni-directional emission pattern (even with a light source comprised of a co-planar arrangement of lighting devices such as LEDs). Various embodiments of the invention may be used to address many of the difficulties associated with utilizing efficient solid state light sources such as LEDs in the fabrication of lamps or bulbs suitable for direct replacement of traditional incandescent bulbs. Embodiments of the invention can be arranged to fit recognized standard size profiles such as those ascribed to commonly used lamps such as incandescent light bulbs, while still providing emission patterns that comply with ENERGY STAR® standards.

This application claims the benefit of U.S. Provisional Patent Application Ser. No. 61/339,516, filed on Mar. 3, 2010, U.S. Provisional Patent Application Ser. No. 61/339,515, filed on Mar. 3, 2010, U.S. Provisional Patent Application Ser. No. 61/366,437, filed on Sep. 24, 2010, U.S. Provisional Application Ser. No. 61/424,665, filed on Dec. 19, 2010, U.S. Provisional Application Ser. No. 61/424,670, filed on Dec. 19, 2010, U.S. Provisional Patent Application Ser. No. 61/434,355, filed on Jan. 19, 2011, U.S. Provisional Patent Application Ser. No. 61/435,326, filed on Jan. 23, 2011, and U.S. Provisional Patent Application Ser. No. 61/435,759, filed on Jan. 24, 2011. This application is also a continuation-in-part from, and claims the benefit of, U.S. patent application Ser. No. 12/848,825, filed on Aug. 2, 2010, U.S. patent application Ser. No. 12/889,719, filed on Sep. 24, 2010, and U.S. patent application Ser. No. 12/975,820, filed on Dec. 22, 2010.

### BACKGROUND OF THE INVENTION

1. Field of the Invention

This invention relates to solid state lamps and bulbs and in particular to efficient and reliable light emitting diode (LED) based lamps and bulbs capable of producing omnidirectional emission patterns.

2. Description of the Related Art

Incandescent or filament-based lamps or bulbs are commonly used as light sources for both residential and commercial facilities. However, such lamps are highly inefficient light sources, with as much as 95% of the input energy lost, primarily in the form of heat or infrared energy. One common alternative to incandescent lamps, so-called compact fluorescent lamps (CFLs), are more effective at converting electricity into light but require the use of toxic materials which, along with its various compounds, can cause both chronic and acute poisoning and can lead to environmental pollution. One solution for improving the efficiency of lamps or bulbs is to use solid state devices such as light emitting diodes (LED or LEDs), rather than metal filaments, to produce light.

Light emitting diodes generally comprise one or more active layers of semiconductor material sandwiched between oppositely doped layers. When a bias is applied across the doped layers, holes and electrons are injected into the active layer where they recombine to generate light. Light is emitted from the active layer and from various surfaces of the LED.

In order to use an LED chip in a circuit or other like arrangement, it is known to enclose an LED chip in a package to provide environmental and/or mechanical protection, color selection, light focusing and the like. An LED package also includes electrical leads, contacts or traces for electrically connecting the LED package to an external circuit. In a typical LED package 10 illustrated in FIG. 1, a single LED chip 12 is mounted on a reflective cup 13 by means of a solder bond or conductive epoxy. One or more wire bonds 11 connect the ohmic contacts of the LED chip 12 to leads 15A and/or 15B, which may be attached to or integral with the reflective cup 13. The reflective cup may be filled with an encapsulant material 16 which may contain a wavelength conversion material such as a phosphor. Light emitted by the LED at a first wavelength may be absorbed by the phosphor, which may responsively emit light at a second wavelength. The entire assembly is then encapsulated in a clear protective resin 14, which may be molded in the shape of a lens to collimate the light emitted from the LED chip 12.

FIG. 2 shows another embodiment of a conventional LED package comprising one or more LED chips 22 mounted onto a carrier such as a printed circuit board (PCB) carrier, substrate or submount 23. A metal reflector 24 mounted on the submount 23 surrounds the LED chip(s) 22 and reflects light emitted by the LED chips 22 away from the package 20. The reflector 24 also provides mechanical protection to the LED chips 22. One or more wire bond connections 27 are made between ohmic contacts on the LED chips 22 and electrical traces 25A, 25B on the submount 23. The mounted LED chips 22 are then covered with an encapsulant 26, which may provide environmental and mechanical protection to the chips while also acting as a lens. The metal reflector 24 is typically attached to the carrier by means of a solder or epoxy bond.

LED chips, such as those found in the LED package 20 of FIG. 2 can be coated by conversion material comprising one or more phosphors, with the phosphors absorbing at least some of the LED light. The LED chip can emit a different wavelength of light such that it emits a combination of light from the LED and the phosphor. The LED chip(s) can be coated with a phosphor using many different methods, with one suitable method being described in U.S. patent application Ser. Nos. 11/656,759 and 11/899,790, both to Chitnis et al. and both entitled “Wafer Level Phosphor Coating Method and Devices Fabricated Utilizing Method”. Alternatively, the LEDs can be coated using other methods such as electrophoretic deposition (EPD), with a suitable EPD method described in U.S. patent application Ser. No. 11/473,089 to Tarsa et al. entitled “Close Loop Electrophoretic Deposition of Semiconductor Devices”.

Lamps have also been developed utilizing solid state light sources, such as LEDs, in combination with a conversion material that is separated from or remote to the LEDs. Such arrangements are disclosed in U.S. Pat. No. 6,350,041 to Tarsa et al., entitled “High Output Radial Dispersing Lamp Using a Solid State Light Source.” The lamps described in this patent can comprise a solid state light source that transmits light through a separator to a disperser having a phosphor. The disperser can disperse the light in a desired pattern and/or changes its color by converting at least some of the light to a different wavelength through a phosphor or other conversion material. In some embodiments the separator spaces the light source a sufficient distance from the disperser such that heat from the light source will not transfer to the disperser when the light source is carrying elevated currents necessary for room illumination. Additional remote phosphor techniques are described in U.S. Pat. No. 7,614,759 to Negley et al., entitled “Lighting Device.”

One potential disadvantage of lamps incorporating remote phosphors is that the volume of phosphor required can be ˜100 times that of the volume required by a conformal or adjacent phosphor arrangement. Phosphors can be quite costly, and the approximate 100× increase in the amount of phosphor required for a remote application necessarily make phosphor a primary cost-driving factor for the production of LED lamp products. Additionally, the supply of certain phosphor types may be limited and/or difficult to increase in the near term to meet the needs of remote phosphor applications.

Further, compared to conformal or adjacent phosphor arrangements where heat generated in the phosphor layer during the conversion process may be conducted or dissipated via the nearby chip or substrate surfaces, remote phosphor arrangements can be subject to inadequate thermally conductive heat dissipation paths. Without an effective heat dissipation pathway, thermally isolated remote phosphors may suffer from elevated operating temperatures that in some instances can be even higher than the temperature in comparable conformal coated layers. This can offset some or all of the benefit achieved by placing the phosphor remotely with respect to the chip. Stated differently, remote phosphor placement relative to the LED chip can reduce or eliminate direct heating of the phosphor layer due to heat generated within the LED chip during operation, but the resulting phosphor temperature decrease may be offset in part or entirely due to heat generated in the phosphor layer itself during the light conversion process and lack of a suitable thermal path to dissipate this generated heat.

Another issue affecting the implementation and acceptance of lamps utilizing solid state light sources relates to the nature of the light emitted by the light source itself. Angular uniformity, also referred to as luminous intensity distribution, is also important for solid state light sources that are to replace standard incandescent bulbs. The geometric relationship between the filament of a standard incandescent bulb and the glass envelope, in combination with the fact that no electronics or heat sink is needed, allow light from an incandescent bulb to shine in a relatively omnidirectional pattern. That is, the luminous intensity of the bulb is distributed relatively evenly across angles in the vertical plane for a vertically oriented bulb from the top of the bulb to the screw base, with only the base itself presenting a significant light obstruction.

In order to fabricate efficient lamps or bulbs based on LED light sources (and associated conversion layers), it is typically desirable to place the LED chips or packages in a co-planar arrangement. This facilitates manufacture and can reduce manufacturing costs by allowing the use of conventional production equipment and processes. However, co-planar arrangements of LED chips typically produce a forward directed light intensity profile (e.g., a Lambertian profile). Such beam profiles are generally not desired in applications where the solid-state lamp or bulb is intended to replace a conventional lamp such as a traditional incandescent bulb, which has a much more omni-directional beam pattern. While it is possible to mount the LED light sources or packages in a three-dimensional arrangement, such arrangements are generally difficult and expensive to fabricate. Solid state light sources also typically include electronic circuitry and a heat sink, which may obstruct the light in some directions.

### SUMMARY OF THE INVENTION

In certain embodiments, the present invention relates to a lighting unit using solid state light sources that conform to the shape and size of industry standard lighting units, such as A19 incandescent or fluorescent light sources, that provide certain improved performance characteristics for such lighting units, such as compliance with ENERGY STAR® performance requirements. These lighting units can be achieved by using various combinations of solid state light sources (such as light emitting diodes), a wavelength conversion material (such as a phosphor), a diffuser element, and a thermal management system/element. In certain embodiments, the solid state light source comprises at least one light emitting diode emitting light of at least a first wavelength. The wavelength conversion material comprises a remote wavelength conversion element over the solid state light source. The wavelength conversion element may comprise at least one phosphor that interacts with the at least one wavelength of light to produce light of at least a second wavelength. The diffuser element is remote from the wavelength conversion element and acts to produce more uniform light emission.

In certain embodiments, the present invention provides lamps and bulbs generally comprising: different combinations and arrangement of a light source; one or more wavelength conversion materials, regions, or layers which are positioned separately or remotely with respect to the light source; and, a separate diffusing layer. This arrangement allows for the fabrication of lamps and bulbs that are efficient and reliable, and can provide an essentially omni-directional emission pattern. Various embodiments of the invention may be used to address many of the difficulties associated with utilizing efficient solid state light sources such as LEDs in the fabrication of lamps or bulbs suitable for direct replacement of traditional incandescent bulbs. Embodiments of the invention can be arranged to fit recognized standard size profiles thereby facilitating direct replacement of such bulbs.

One embodiment of a lighting device according to the present invention comprises a solid state light source with a diffuser element and a wavelength conversion element. The diffuser element is spaced apart from said light source. The wavelength conversion element is also spaced apart from said light source and from said diffuser element, and comprises one or more distinct phosphor layers for converting the wavelength(s) of light emitted from said light source.

Another embodiment of a lighting device according to the present invention comprises a solid state light source, a diffuser element, and a wavelength conversion element. The diffuser element is disposed over said light source. The wavelength conversion element is also disposed over said light source. The wavelength conversion element further comprises one or more distinct phosphor layers for converting the wavelength(s) of light emitted from the light source.

One embodiment of a solid state lamp according to the present invention comprises a solid state light source, a diffuser element, and a wavelength conversion element. The diffuser element is over and spaced apart from the light source. The wavelength conversion element is over and spaced apart from the light source and is over and spaced apart from the diffuser element. The wavelength conversion element comprises one or more distinct phosphor layers for converting the wavelength(s) light emitted from the light source. The diffuser element and the wavelength conversion element provide a double-globe structure.

Another embodiment of a solid state lamp according to the present invention comprises a solid state light source, a diffuser element, and a wavelength conversion element. The diffuser element is over and spaced apart from the light source. The wavelength conversion element is over and spaced apart from the light source, with the wavelength conversion element comprising one or more distinct phosphor layers for converting the wavelength(s) of light emitted from the light source. The diffuser element is over and spaced apart from the wavelength conversion element, and the diffuser element and wavelength conversion element provides a double-globe structure.

These and other aspects and advantages of the invention will become apparent from the following detailed description and the accompanying drawings which illustrate by way of example the features of the invention.

### BRIEF DESCRIPTION OF THE DRAWINGS

FIG. 1 shows a sectional view of one embodiment of a prior art LED package;

FIG. 2 shows a sectional view of another embodiment of a prior art LED package;

FIG. 3 shows the size specifications for an A19 replacement bulb;

FIG. 4 is a sectional view of one embodiment of a lamp according to the present invention;

FIG. 5 is a sectional view of one embodiment of a lamp according to the present invention;

FIGS. 6-8 are sectional views of different embodiments of a conversion element according to the present invention;

FIG. 9 is a sectional view of one embodiment of a lamp according to the present invention; and

FIG. 10 is a sectional view of one embodiment of a lamp according to the present invention.

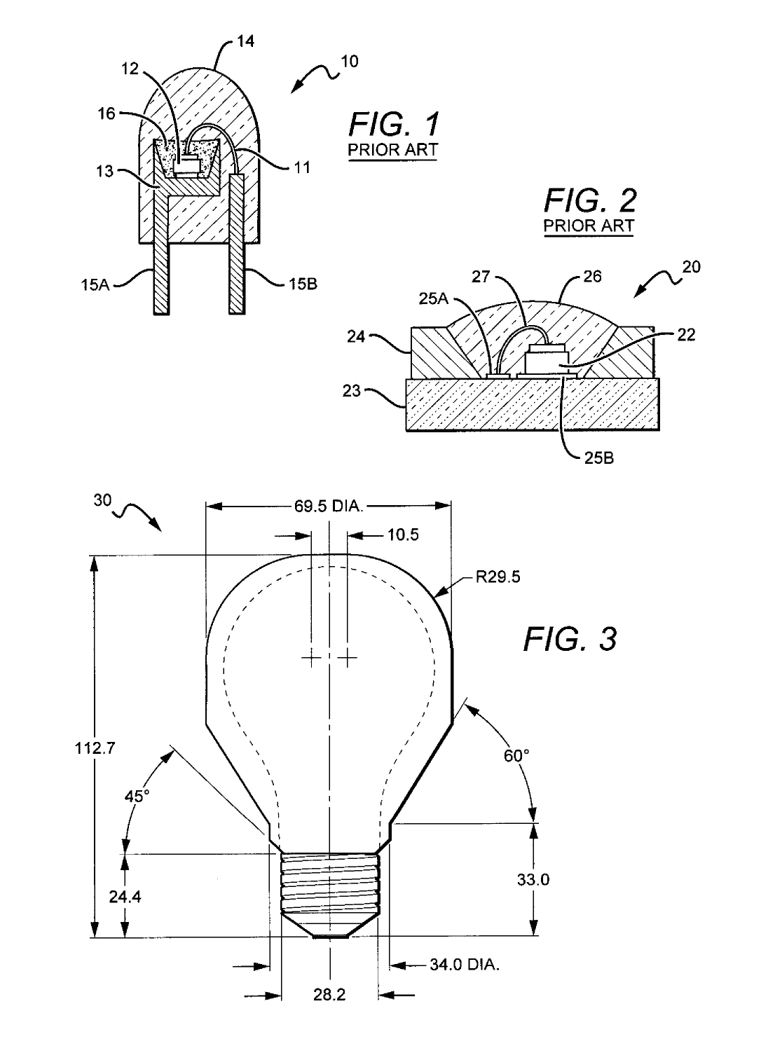

### DETAILED DESCRIPTION OF THE INVENTION

The present invention is described herein with reference to certain embodiments, but it is understood that the invention can be embodied in many different forms and should not be construed as limited to the embodiments set forth herein.

The present invention is directed to different embodiments of lamp or bulb structures that are efficient, reliable, and cost effective. In some embodiments, the lamp or bulb structures can provide an essentially omnidirectional emission pattern from directional emitting light sources, such as forward emitting light sources. Also, in some embodiments of the present invention, the lamp or bulb structures utilize solid state emitters with remote light conversion materials and remote diffusing elements. Further, in some embodiments the conversion material may comprise one or more distinct layers of a single or multiple phosphor, with the order and number of phosphor layers variable and dependent upon the desired emission characteristics of the device as well as the types/colors of the light sources and the types/colors of the phosphors used. The phosphor layers may or may not be remote from the light source. In some embodiments, the diffuser disperses or redistributes the light from the remote phosphor and/or the lamp's light source into a desired emission pattern. In some embodiments the diffuser globe can be arranged to disperse forward directed emission pattern into a more omnidirectional pattern useful for general lighting applications.

Some embodiments of lamps according to the present invention can have a conversion material over and spaced apart from the light source. A diffuser can also be included that is spaced apart from the conversion material, such that the lamp exhibits a double-globe structure. The spaces between the various structures can comprise light mixing chambers that can promote not only dispersion of, but also color uniformity of the lamp emission. The space between the light source and conversion material or diffuser, as well as the space between the conversion material and diffuser, can serve as light mixing chambers. Other embodiments can comprise additional conversion materials or diffusers that can form additional mixing chambers. The order of the conversion materials and diffusers can be different such that some embodiments can have a diffuser inside a conversion material, with the spaces between forming light mixing chambers. These are only a few of the many different conversion material and diffuser arrangements according to the present invention.

Some lamp embodiments according to the present invention can comprise a light source having a co-planar arrangement of one or more LED chips or packages, with the emitters being mounted on a flat or planar surface. In other embodiments, the LED chips can be non co-planar, such as being on a pedestal or other three-dimensional structure. Co-planar light sources can reduce the complexity of the emitter arrangement, making them both easier and cheaper to manufacture. Co-planar light sources, however, tend to emit primarily in the forward direction such as in a Lambertian emission pattern. In different embodiments it can be desirable to emit a light pattern mimicking that of conventional incandescent light bulbs that can provide near uniform emission intensity and color uniformity at different emission angles. Different embodiments of the present invention can comprise features that can transform the emission pattern from the non-uniform to substantially uniform within a range of viewing angles.

In some embodiments, a conversion region can comprise a material that is at least partially transparent to light from the light source, and at least one phosphor material layer which absorbs light from the light source and emits a different wavelength of light. The diffuser can comprise a scattering film/particles and associated carrier such as a glass enclosure, and can serve to scatter or re-direct at least some of the light emitted by the light source and/or phosphor layer(s) to provide a desired beam profile. The properties of the diffuser, such as geometry, scattering properties of the scattering layer, surface roughness or smoothness, and spatial distribution of the scattering layer properties may be used to control various lamp properties such as color uniformity and light intensity distribution as a function of viewing angle. The diffuser may also provide a desired overall lamp appearance when the bulb/lamp is not illuminated by masking the phosphor layers and other internal lamp features.

A heat sink structure may also be included which can be in thermal contact with the light source, the phosphor layers and/or diffuser, and other lamp elements to dissipate heat into the surrounding ambient. Electronic circuits may also be included to provide electrical power to the light source and other capabilities such as dimming, etc., and the circuits may include a means by which to apply power to the lamp, such as an Edison socket, etc.

Different embodiments of the lamps can have many different shapes and sizes, with some embodiments having dimensions to fit into standard size envelopes, such as the A19 size envelope 30 as shown in FIG. 3. This makes the lamps particularly useful as replacements for conventional incandescent and fluorescent lamps or bulbs, with lamps according to the present invention experiencing the reduced energy consumption and long life provided from their solid state light sources. The lamps according to the present invention can also fit other types of standard size profiles including but not limited to A21 and A23.

In some embodiments the light sources can comprise solid state light sources, such as different types of LEDs, LED chips, or LED packages. In some embodiments a single LED chip or package can be used, while in others multiple LED chips or packages can be arranged in different types of arrays. By having good thermal dissipation and the phosphor layer(s) thermally isolated from LED chips, the LED chips can be driven by higher current levels without causing detrimental effects to the conversion efficiency and long-term reliability of the phosphor layer(s). This can allow for the flexibility to overdrive the LED chips to lower the number of LEDs needed to produce the desired luminous flux. This in turn can reduce the cost on complexity of the lamps. These LED packages can comprise LEDs encapsulated with a material that can withstand the elevated luminous flux or can comprise unencapsulated LEDs.

Some LED lamps according to the present invention can have a correlated color temperature (CCT) from about 1200K to 3500K, while others can emit light with a luminous intensity distribution that varies by not more than 10% from 0 to 150 degrees from the top of the lamp. In other embodiments, lamps can emit light with a luminous intensity distribution that varies by not more than 20% from 0 to 135 degrees. In some embodiments, at least 5% of the total flux from the lamps is in the 135-180 degree zone. Other embodiments can emit light having a luminous intensity distribution that varies by not more than 30% from 0 to 120 degrees. In some embodiments, the LED lamp has a color spatial uniformity of such that chromaticity with change in viewing angle varies by no more than 0.004 from a weighted average point. Other lamps can conform to the operational requirements for luminous efficacy, color spatial uniformity, light distribution, color rendering index, dimensions, and base type for a 60-watt incandescent replacement bulb.

As described in more detail below, the LED lamps according to the present invention can have many different types of emitters that emit different wavelength spectrums of light. In some embodiments, a lighting unit according to the principles of the present invention emits light in at least three peak wavelengths (e.g., blue, yellow, and red). At least a first wavelength is emitted by the solid state light source, such as blue light, and at least a second wavelength is emitted by the wavelength conversion element (such as green and/or yellow light). Depending on the embodiment, a third wavelength of light (such as green and/or red light), can be emitted by the solid state light source and/or the wavelength conversion element. In some embodiments, the at least three wavelengths can be emitted by the wavelength conversion element or the solid state light source. In some embodiments, the solid state light source can emit overlapping, similar or the same wavelengths of light as the wavelength conversion material. For example, the solid state light source can comprise LEDs that emit a wavelength of light (e.g. red light) that overlaps or is substantially the same as light emitted by phosphor layer(s) in the wavelength conversion material (e.g., red phosphor added to a yellow phosphor in the wavelength conversion material).

In some embodiments, the solid state light source comprises at least one additional LED that emits light having at least one different peak wavelength of light, and/or the wavelength conversion material comprises at least one additional phosphor emitting at least one different peak wavelength. Accordingly, the lighting unit emits light having at least four different peak wavelengths of light.

Depending on the embodiment, the solid state light source can comprise single or multiple strings of LEDs. The wavelength conversion element can include phosphor layers that are dispensed over the solid state light source and/or positioned remote from the solid state light source as a distinct wavelength conversion element. A lighting unit using a wavelength conversion material that is dispensed on individual LEDs in a solid state light source is described in U.S. patent application Ser. No. 12/975,820 to van de Ven et al., entitled “LED Lamp with High Color Rendering Index,” assigned to Cree, Inc. and incorporated herein by reference. The wavelength conversion element can include phosphor layer(s) on an inside and/or outside surface of a conversion element and/or embedded or integral with a conversion element. The diffuser element can include diffuser particles coated on an inside and/or outside surface of the diffuser and/or embedded within or integral with the diffuser. In some embodiments, the diffuser comprises structures or features, such as scouring or roughening.

In some embodiments of the invention, the LED assembly includes LED packages emitting blue light and with others emitting red light. In some embodiments, the LED assembly of the LED lamp includes an LED array with at least two groups of LEDs, wherein one group, if illuminated, would emit light having dominant wavelength from 440 to 480 nm, and another group, if illuminated, would emit light having a dominant wavelength from 605 to 630 nm. The phosphors can be arranged to absorb and re-emit light from one or both of the two wavelength spectrum and can have one or more distinct phosphor layers comprising single or mixed phosphor types, each of which can absorb light and re-emit a different wavelength of light. Some lamp embodiments can comprise a plurality of LEDs emitting blue and red light, with the wavelength conversion element comprising a yellow phosphor that absorbs blue light and re-emits yellow or green light, with a portion of the blue light passing through the phosphor layer. The red light from the red LED(s) passes through the yellow/green phosphor while experiencing little or no absorption, such that the lamp emits a white light combination of blue, yellow/green and red. In still other embodiments, blue and red LED(s) can be provided, with the phosphor layers comprising yellow/green phosphor and a red phosphor to contribute to the red component of the lamp lighting and to assist in dispersing the LED light.

In some embodiments, the LEDs can comprise two groups, with one group of LEDs being interconnected in a first serial string, and the other group of LEDs interconnected in a second serial string. This is only one of the many ways that the LEDs can be interconnected and it is understood that the LEDs can be arranged in many different parallel and serial interconnect combinations.

The lamps according to the present invention can emit light with a high color rendering index (CRI), such as 80 or higher in some embodiments. In some other embodiments, the lamps can emit light with CRI of 90 or higher. The lamps can also produce light having a correlated color temperature (CCT) from 2500K to 3500K. In other embodiments, the light can have a CCT from 2700K to 3300K. In still other embodiments, the light can have a CCT from about 2725K to about 3045K. In some embodiments, the light can have a CCT of about 2700K or about 3000K. In still other embodiments, where the light is dimmable, the CCT may be reduced with dimming. In such a case, the CCT may be reduced to as low as 1500K or even 1200K. In some embodiments, the CCT can be increased with dimming. Depending on the embodiment, other output spectral characteristics can be changed based on dimming.

It should be noted that other arrangements of LEDs can be used with embodiments of the present invention. The same number of each type of LED can be used, and the LED packages can be arranged in varying patterns. A single LED of each type could be used. Additional LEDs, which produce additional colors of light, can be used. By using one or more LEDs emitting one or more additional colors and/or a wavelength conversion element comprising one or more additional phosphors or phosphor layers, the CRI of the lighting unit can be increased. Lumiphors can be used with all the LED modules. A single lumiphor can be used with multiple LED chips and multiple LED chips can be included in one, some or all LED device packages. A further detailed example of using groups of LEDs emitting light of different wavelengths to produce substantially white light can be found in issued U.S. Pat. No. 7,213,940, which is incorporated herein by reference.

Some lamp embodiments according to the present invention can comprise a first group of solid state light emitters and a first group of lumiphors, with the first group of lumiphors including at least one lumiphor. The lamps also include a second group of solid state light emitters, with the second group of solid state light emitters including at least one solid state light emitter and at least a first power line. Each of the first group of solid state light emitters and each of the second group of solid state light emitters can be electrically connected to the first power line. Each of said first group of solid state light emitters, if illuminated, can emit light having a dominant wavelength in the range of from 430 nm to 480 nm. Each of said first group of lumiphors, if excited, can emit light having a dominant wavelength in the range of from about 555 nm to about 585 nm. Each of the second group of solid state light emitters, if illuminated, can emit light having a dominant wavelength in the range of from 600 nm to 630 nm.

If current is supplied to the first power line a combination of (1) light exiting the lighting device which was emitted by the first group of solid state light emitters, (2) light exiting the lighting device which was emitted by the first group of lumiphors, and (3) light exiting the lighting device which was emitted by the second group of solid state light emitters would, in an absence of any additional light, produce a mixture of light having x, y coordinates on a 1931 CIE Chromaticity Diagram. The coordinates define a point that is within ten MacAdam ellipses of at least one point on the blackbody locus on a 1931 CIE Chromaticity Diagram. This combination of light also produces a sub-mixture of light having x, y color coordinates which define a point which is within an area on a 1931 CIE Chromaticity Diagram enclosed by first, second, third, fourth and fifth connected line segments defined by first, second, third, fourth and fifth points. The first point can have x, y coordinates of 0.32, 0.40, the second point can have x, y coordinates of 0.36, 0.48, the third point can have x, y coordinates of 0.43, 0.45, the fourth point can have x, y coordinates of 0.42, 0.42, and the fifth point can have x, y coordinates of 0.36, 0.38.

The present invention also provides LED lamps with relative geometries of features such as the LED heat dissipation devices or heat sinks that allow for lamp emission patterns that meet the requirements of the ENERGY STAR® Program Requirements for Integral LED Lamps, amended Mar. 22, 2010, herein incorporated by reference. The relative geometries allow light to disperse within 20% of mean value from 0 to 135 degrees with greater than 5% of total luminous flux in the 135 to 180 degree zone (measurement at 0, 45 and 90 azimuth angles). The relative geometries include the LED assembly mounting width, height, head dissipation devices width and unique downward chamfered angle. Combined with a globe-shaped wavelength conversion element according to the present invention and/or a reflective umbrella and diffuser dome, the geometries will allow light to disperse within these stringent ENERGY STAR® requirements. The present invention can reduce the surface areas needed to dissipate LED and power electronics' thermal energy and still allow the lamps to comply with ANSI A19 lamp profiles.

The present invention also provides for lamps with enhanced emission efficiencies, with some lamps according to the present invention emitting with an efficiency of 65 or more lumens per watt (LPW). In other embodiments the lamps can emit light at an efficiency of 80 or more LPW. In all these embodiments the lamp can emit light with a more desirable color temperature (e.g. 3000K or less or in some embodiments 2700K or less) and a more desirable color rendering index (e.g. 90 or greater CRI).

Some lamp embodiments according to the present invention can emit light of 700 lumens or greater, while others can emit light of 750 lumens or greater. Still other lamp embodiments can emit 800 lumens or greater, with some of these emitting this light from 10 watts or less. These emissions can provide the desired brightness while providing the additional advantage of being able to pass less stringent statutory (e.g. ENERGY STAR®) testing for lamps operating from less than 10 W. This can result in lamps that can be brought to market faster. This emission efficiency can be the result of many factors, such as maximized surface area for a thermal management system, optimized optics resulting in blocking of a minimal amount of light, and the use of a remote conversion element which can result in higher efficacy (80 lumens per watt or greater) than emitters having a conformal coated conversion material (although some embodiments can include emitters with conformal coated wavelength converter elements).

Accordingly, embodiments of the lighting unit according to aspects of the present invention can be used to provide LED-based replacement A-Lamp for standard incandescent 60 Watt incandescent light bulbs that can meet ENERGY STAR® performance requirements. Other embodiments can provide LED replacement A-Lamp lighting units for higher wattage incandescent bulbs, such as standard 75 Watt or 100 Watt incandescent A19 light bulbs. In other embodiments, the lighting unit could replace standard 40 Watt incandescent A19 bulbs. Other embodiments of the lighting unit according to aspects of the present invention can be used to replace other standard shaped incandescent or fluorescent lights.

Different lamp embodiments can also comprise components arranged such that the lamps exhibit a relatively long lifetime. In some embodiments the lifetime can be 25,000 hours or more, while in other embodiments it can be 40,000 hours or more. In still other embodiments the lifetime can be 50,000 hours or more. These extended lifetimes can be at operating efficiency of, for example, lumens per watt or more, and can be at different temperatures such as 25° C. and/or 45° C. This lifetime can be measured using a number of different methods. The first can be simply running the lamps for their lifetime until they fail. This can, however, often require extended periods of time that make this method impractical in certain circumstances. Another acceptable method is calculating the lamp lifetime by using the lifetime of each component used in lamp. This information is often provided by the component manufacturers, and often lists operating lifetime under different operating conditions, such as temperature. This data can then be utilized using known methods to calculate the lifetime of the lamp. A third acceptable method is to accelerate the lifetime of the lamp by operating it under elevated conditions such as higher temperature or elevated power or switching signals. This can cause early lamp failure, with this date then utilized in known methods to determine the operating lifetime of the lamp under normal operating conditions.

Different embodiments of the present invention can also comprise safety features that protect against the exposure of certain electrical features or elements in the event that one or both of the diffuser globe/dome and conversion element globe are broken. These safety features reduce and/or eliminate the danger of electrical shock from coming in contact with these electrical features, and in some embodiments these safety features can comprise different arrangements of electrically insulating materials covering the electrical features.

The present invention provides a unique combination of features and characteristics that allow for long lifetime and efficient operation in a simple and relatively inexpensive arrangement. The lamp can operate at an efficacy of 80 lumens per watt or better, while still producing a CRI of 80 and higher, or 90 and higher. In some embodiments, this efficacy can be achieved at less than 10 watts. This can be provided in a lamp having LEDs as its light source, and a double dome diffuser and conversion material arrangement, while still fitting in an A19 size envelope and emitting a uniform light distribution in compliance with ENERGY STAR® requirements. Lamps with this arrangement can also emit light having a temperature of 3000K and less, or 2700K or less.

The present invention is described herein with reference to certain embodiments, but it is understood that the invention can be embodied in many different forms and should not be construed as limited to the embodiments set forth herein. In particular, the present invention is described below in regards to certain lamps having one or multiple LEDs or LED chips or LED packages in different configurations, but it is understood that the present invention can be used for many other lamps having many different configurations. Examples of different lamps arranged in different ways according to the present invention are described below and in U.S. Provisional Patent application Ser. No. 61/435,759, to Le et al., entitled “Solid State Lamp”, filed on Jan. 24, 2011, and incorporated herein by reference.

The embodiments below are described with reference to LED of LEDs, but it is understood that this is meant to encompass LED chips and LED packages. The components can have different shapes and sizes beyond those shown and different numbers of LEDs can be included. It is also understood that the embodiments described below utilize co-planar light sources, but it is understood that non co-planar light sources can also be used. It is also understood that the lamp's LED light source may be comprised of one or multiple LEDs, and in embodiments with more than one LED, the LEDs may have different emission wavelengths. Similarly, some LEDs may have adjacent or contacting phosphor layers or regions, while others may have either adjacent phosphor layers of different composition or no phosphor layers at all.

The present invention is described herein with reference to conversion materials, wavelength conversion materials, remote phosphors, phosphors, phosphor layers and related terms. The use of these terms should not be construed as limiting. It is understood that the use of the term remote phosphors, phosphor or phosphor layers is meant to encompass and be equally applicable to all wavelength conversion materials.

Some of the embodiments described herein comprise a remote phosphor and a separate remote diffuser arrangement, with some being in a double globe/dome arrangement. It is understood that in other embodiments there can be a single dome like structure having both the conversion and diffusing properties, or there can be more than two domes with different combinations of conversion materials and diffusers. The conversion material and diffusers can be provided in respective globes/domes, or the conversion material and diffusers can be together on one or more of the globes/domes. The term globe or dome should not be construed as limited to any particular shape. The term can encompass many different three dimensional shapes, including but not limited to bullet-shaped, spherical, tube-shaped/elongated, or a squashed configuration.

The present invention is described herein with reference to conversion materials, phosphor layers and diffusers being remote to one another. Remote in this context refers to being spaced apart from and/or to not being on or in direct thermal contact. It is further understood that when discussing dominant wavelengths, there is range or width of wavelengths surrounding a dominant wavelength, so that when discussing a dominant wavelength the present invention is meant to cover a range of wavelengths around that wavelength.

It is also understood that when an element such as a layer, region or substrate is referred to as being “on” another element, it can be directly on the other element or intervening elements may also be present. Furthermore, relative terms such as “inner”, “outer”, “upper”, “above”, “lower”, “beneath”, and “below”, and similar terms, may be used herein to describe a relationship of one layer or another region. It is understood that these terms are intended to encompass different orientations of the device in addition to the orientation depicted in the figures.

Although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Embodiments of the invention are described herein with reference to cross-sectional view illustrations that are schematic illustrations of embodiments of the invention. As such, the actual thickness of the layers can be different, and variations from the shapes of the illustrations as a result, for example, of manufacturing techniques and/or tolerances are expected. Embodiments of the invention should not be construed as limited to the particular shapes of the regions illustrated herein but are to include deviations in shapes that result, for example, from manufacturing. A region illustrated or described as square or rectangular will typically have rounded or curved features due to normal manufacturing tolerances. Thus, the regions illustrated in the figures are schematic in nature and their shapes are not intended to illustrate the precise shape of a region of a device and are not intended to limit the scope of the invention.

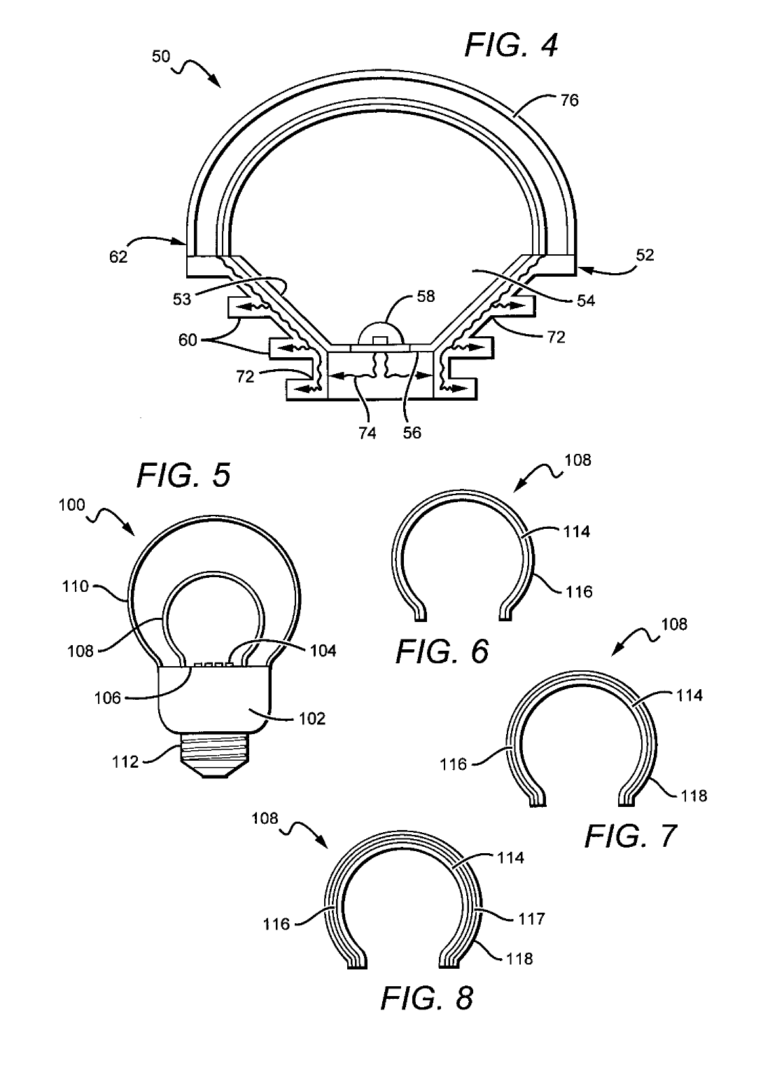

FIG. 4 shows one embodiment of a lamp 50 according to the present invention that comprises a heat sink structure 52 having an optical cavity 54 with a platform 56 for holding a light source 58. Although this embodiment and some embodiments below are described with reference to an optical cavity, it is understood that many other embodiments can be provided without optical cavities. These can include, but are not limited to, light sources being on a planar surface of the lamp structure or on a pedestal. The light source 58 can comprise many different emitters with the embodiment shown comprising an LED. Many different commercially available LED chips or LED packages can be used including but not limited to those commercially available from Cree, Inc. located in Durham, N.C. It is understood that lamp embodiments can be provided without an optical cavity, with the LEDs mounted in different ways in these other embodiments. By way of example, the light source can be mounted to a planar surface in the lamp or a pedestal can be provided for holding the LEDs.

The light source 58 can be mounted to the platform using many different known mounting methods and materials with light from the light source 58 emitting out the top opening of the cavity 54. In some embodiments light source 58 can be mounted directly to the platform 56, while in other embodiments the light source can be included on a submount or printed circuit board (PCB) that is then mounted to the platform 56. The platform 56 and the heat sink structure 52 can comprise electrically conductive paths for applying an electrical signal to the light source 58, with some of the conductive paths being conductive traces or wires. Portions of the platform 56 can also be made of a thermally conductive material and in some embodiments heat generated during operation can spread to the platform and then to the heat sink structure.

The heat sink structure 52 can at least partially comprise a thermally conductive material, and many different thermally conductive materials can be used including different metals such as copper or aluminum, or metal alloys. Copper can have a thermal conductivity of up to 400 W/m-k or more. In some embodiments the heat sink can comprise high purity aluminum that can have a thermal conductivity at room temperature of approximately 210 W/m-k. In other embodiments the heat sink structure can comprise die cast aluminum having a thermal conductivity of approximately 200 W/m-k. The heat sink structure 52 can also comprise other heat dissipation features such as heat fins 60 that increase the surface area of the heat sink to facilitate more efficient dissipation into the ambient. In some embodiments, the heat fins 60 can be made of material with higher thermal conductivity than the remainder of the heat sink. In the embodiment shown the fins 60 are shown in a generally horizontal orientation, but it is understood that in other embodiments the fins can have a vertical or angled orientation. In still other embodiments, the heat sink can comprise active cooling elements, such as fans, to lower the convective thermal resistance within the lamp. In some embodiments, heat dissipation from the conversion element is achieved through a combination of convection thermal dissipation and conduction through the heat sink structure 52. Different heat dissipation arrangements and structures are described in U.S. Patent Application Ser. No. 61/339,516, to Tong et al., entitled “LED Lamp Incorporating Remote Phosphor with Heat Dissipation Features and Diffuser Element,” which is assigned to the same assignee of the present invention and is incorporated herein by reference.

Reflective layers 53 can also be included on the heat sink structure 52, such as on the surface of the optical cavity 54. In those embodiments not having an optical cavity the reflective layers can be included around the light source. In some embodiments the surfaces can be coated with a material having a reflectivity of approximately 75% or more to the lamp visible wavelengths of light emitted by the light source 58 and/or wavelength conversion element (“the lamp light”), while in other embodiments the material can have a reflectivity of approximately 85% or more to the lamp light. In still other embodiments the material can have a reflectivity to the lamp light of approximately 95% or more.

The heat sink structure 52 can also comprise features for connecting to a source of electricity such as to different electrical receptacles. In some embodiments the heat sink structure can comprise a feature of the type to fit in conventional electrical receptacles. For example, it can include a feature for mounting to a standard Edison socket, which can comprise a screw-threaded portion which can be screwed into an Edison socket. In other embodiments, it can include a standard plug and the electrical receptacle can be a standard outlet, or can comprise a GU24 base unit, or it can be a clip and the electrical receptacle can be a receptacle which receives and retains the clip (e.g., as used in many fluorescent lights). These are only a few of the options for heat sink structures and receptacles, and other arrangements can also be used that safely deliver electricity from the receptacle to the lamp 50.

The lamps according to the present invention can comprise a power supply or power conversion unit that can comprise a driver to allow the bulb to run from an AC line voltage/current and to provide light source dimming capabilities. In some embodiments, the power supply can be housed in a cavity/housing within the lamps heat sink (not shown) and can comprise an offline constant-current LED driver using a non-isolated quasi-resonant fly-back topology. The LED driver can fit within the lamp and in some embodiments can comprise a 25 cubic centimeter volume or less, while in other embodiments it can comprise an approximately 22 cubic centimeter volume or less and still in other embodiments 20 cubic centimeters or less. In some embodiments the power supply can be non-dimmable but is low cost. It is understood that the power supply used can have different topology or geometry and can be dimmable as well. Embodiments having a dimmer can exhibit many different dimming characteristics such as phase cut dimmable down to 5% (both leading and trailing edge). In some dimming circuits according to the present invention, the dimming is realized by decreasing the output current to the LEDs.

The power supply unit can comprise many different components arranged on printed circuit boards in many different ways. The power supply can operate from many different power sources and can exhibit may different operating characteristics. In some embodiments the power supply can be arranged to operate from a 120 volts alternating current (VAC) ±10% signal while providing a light source drive signal of greater than 200 milliamps (mA) and/or greater than 10 volts (V). In other embodiments the drive signal can be greater than 300 mA generate power and/or greater than 15V. In some embodiments the drive signal can be approximately 400 mA and/or approximately 22V.

The power supply can also comprise components that allow it to operate with a relatively high level of efficiency. One measure of efficiency can be the percentage of input energy to the power supply that is actually output as light from the lamp light source. Much of the energy can be lost through the operation of the power supply. In some lamp embodiments, the power supply can operate such that more than 10% of the input energy to the power supply is radiated or output as light from the LEDs. In other embodiments more than 15% of the input energy is output as LED light. In still other embodiments, approximately 17.5% of input energy is output as LED light, and in others approximately 18% or greater input energy is output as LED light.

A thermal potting material or other suitable thermally conductive material can be included around the power supply for protection and to assist in radiating heat away from the power supply components. In the embodiment where the power supply is in the heat sink cavity, the thermal potting material can fill all or part of the cavity such that it surrounds the power supply. Many different thermally conductive materials can be used that exhibit some or all of the characteristics of being safe, electrically insulating, thermally conductive, having low thermal expansion, and viscous enough that it would not run out of cracks in the heat sink cavity prior to being cured. Some embodiments can use potting compounds comprising epoxy and fiberglass such as those available from Dow Corning, Inc.

A wavelength conversion element 62 is included over the light source 58 and a diffuser element 76 is included over the conversion element 62. In the embodiment shown, both the conversion element 62 and diffuser element 76 are generally dome-shaped. However, it is understood that the elements are depicted for illustrative purposes only, and they are not limited to these particular shapes and/or configurations. It is understood that the cavity opening (if there is one), the diffuser, and the conversion element can be many different shapes and sizes. It is also understood that the conversion element 62 can cover less than the entire cavity opening. As further described below, the diffuser 76 is arranged to disperse the light from the conversion element 62 and/or LED into the desired lamp emission pattern and can comprise many different shapes and sizes depending on the light it receives and the desired lamp emission pattern.

Embodiments of conversion elements according to the present invention can be characterized as comprising distinct layers and/or regions of conversion material (such as phosphors) and thermally conductive light transmitting material, but it is understood that conversion elements can also be provided that are not thermally conductive. The light transmitting material can be transparent to the light emitted from the light source 58 and the conversion material(s) should be of the type that absorbs the wavelength of light from the light source and re-emits a different wavelength of light. In the embodiment shown, the thermally conductive light transmitting material comprises a carrier layer 64 and the conversion material comprises one or more distinct phosphor layers 66 on the carrier. As further described below, different embodiments can comprise many different arrangements of the thermally conductive light transmitting material and conversion material.

When light from the light source 58 is absorbed by the phosphor(s) in the phosphor layer(s) 66, it is re-emitted in isotropic directions with approximately 50% of the light emitting forward and 50% emitting backward into the cavity 54 and/or back toward the light source 58. In prior LEDs having conformal-coated phosphor layers, a significant portion of the light emitted backwards can be directed back into the LED and its likelihood of escaping is limited by the extraction efficiency of the LED structure. For some LEDs, the extraction efficiency can be approximately 70%, so a percentage of the light directed from the conversion material back into the LED can be lost. In the lamps according to the present invention, having the remote phosphor configuration with LEDs on platform 56 at the bottom of cavity 54, a higher percentage of the backward phosphor light strikes a surface of the cavity and/or platform instead of the LED. Coating these surfaces with a reflective layer 53 increases the percentage of light that reflects back into the phosphor layer 66 where it can emit from the lamp. These reflective layers 53 allow for the optical cavity to effectively recycle photons, and increase the emission efficiency of the lamp. It is understood that the reflective layer can comprise many different materials and structures including but not limited to reflective metals or multiple layer reflective structures such as distributed Bragg reflectors. Reflective layers can also be included around the LEDs in those embodiments not having an optical cavity.

The carrier layer 64 can be made of many different materials having a thermal conductivity of 0.5 W/m-k or more, such as quartz, silicon carbide (SiC) (thermal conductivity ˜120 W/m-k), glass (thermal conductivity of 1.0-1.4 W/m-k) or sapphire (thermal conductivity of ˜40 W/m-k). In other embodiments, the carrier layer 64 can have thermal conductivity greater than 1.0 W/m-k, while in other embodiments it can have thermal conductivity of greater than 5.0 W/m-k. In still other embodiments it can have a thermal conductivity of greater that 10 W/m-k. In some embodiments the carrier layer can have thermal conductivity ranging from 1.4 to 10 W/m-k. The phosphor carrier can also have different thicknesses depending on the material being used, with a suitable range of thicknesses being 0.1 mm to 10 mm or more. It is understood that other thicknesses can also be used depending on the characteristics of the material for the carrier layer. The material should be thick enough to provide sufficient lateral heat spreading for the particular operating conditions. Generally, the higher the thermal conductivity of the material, the thinner the material can be while still providing the necessary thermal dissipation. Different factors can impact which carrier layer material is used including but not limited to cost and transparency to the light source light. Some materials may also be more suitable for larger diameters, such as glass or quartz. These can provide reduced manufacturing costs by formation of the phosphor layer(s) on the larger diameter carrier layers and then singulation into the smaller carrier layers. In some embodiments, the carrier can comprise a polymer or plastic material with the phosphor layer(s) coated on the inside surface and/or outside surface of the phosphor carrier and/or embedded or mixed in with the polymer or plastic.

Many different phosphors can be used in the phosphor layer(s) 66, with the present invention being particularly adapted to lamps emitting white light. As described above, in some embodiments the light source 58 can be LED-based and can emit light in the blue wavelength spectrum, although it is understood that the LEDs can emit a wide range of colors and/or color combinations. Each phosphor layer can absorb some of the light emitted from the LED(s). For example, a yellow phosphor layer can absorb some of the blue light emitted from a blue LED configuration, and re-emit yellow light. This allows the lamp to emit a white light combination of blue and yellow light. In some embodiments, blue LED light can be converted by a yellow conversion material using a commercially available YAG:Ce phosphor, although a full range of broad yellow spectral emission is possible using conversion particles made of phosphors based on the (Gd,Y)₃(Al,Ga)₅O₁₂:Ce system, such as the Y₃Al₅O₁₂:Ce (YAG). Other yellow phosphors that can be used for creating white light when used with a blue emitting LED based emitter include, but are not limited to: Tb₃₋ₓREₓO₁₂:Ce(TAG); RE=Y, Gd, La, Lu; or Sr_{2-x-y}BaₓCa_{y}SiO₄:Eu.

The conversion element can also be arranged with more than one phosphor either mixed in with the phosphor layer 66, or as a second distinct phosphor layer on or to the inside of the carrier layer 64. In some embodiments, each of the two distinct phosphor layers can absorb the LED light and can re-emit different colors of light. In these embodiments, the colors from the two phosphor layers can be combined for higher CRI white of different white hue (warm white). This can include light from yellow phosphors above that can be combined with light from red phosphors. Different red phosphors can be used including:

SrₓCa₁₋ₓS:Eu, Y; Y=halide;

### CaSiAlN₃:Eu; or

### Sr_{2-y}Ca_{y}SiO₄:Eu

Other phosphors can be used to create color emission by converting substantially all light to a particular color. For example, the following phosphors can be used to generate green light:

### SrGa₂S₄:Eu;

### Sr_{2-y}Ba_{y}SiO₄:Eu; or

### SrSi₂O₂N₂:Eu.

The following lists some additional suitable phosphors that may be used as conversion particles in phosphor layer(s) 66, although others can be used. Each exhibits excitation in the blue and/or UV emission spectrum, provides a desirable peak emission, has efficient light conversion, and has acceptable Stokes shift:

### Yellow/Green

### (Sr,Ca,Ba) (Al,Ga)₂S₄:Eu²⁺

### Ba₂(Mg,Zn)Si₂O₇:Eu²⁺

### Gd_{0.46}Sr_{0.31}Al_{1.23}OₓF_{1.38}:Eu²⁺_{0.06}

### (Ba_{1-x-y}SrₓCa_{y})SiO₄:Eu

### Ba₂SiO₄:Eu²⁺

Lu₃Al₅O₁₂ doped with Ce³⁺
(Ca,Sr,Ba)Si₂O₂N₂ doped with Eu²⁺

### CaSc2O4:Ce³⁺

### (Sr,Ba)2SiO4:Eu²⁺

### Red

### Lu₂O₃:Eu³⁺

### Sr₂₋ₓLaₓ) (Ce₁₋ₓEuₓ)O₄

### Sr₂Ce₁₋ₓEuₓO₄

### Sr₂₋ₓEuₓCeO₄

### SrTiO₃:Pr³⁺,Ga³⁺

### CaAlSiN₃:Eu²⁺

### Sr₂Si₅N₈:Eu²⁺

Different sized phosphor particles can be used including but not limited to particles in the range of 10 nanometers (nm) to 30 micrometers (μm), or larger. Smaller particle sizes typically scatter and mix colors better than larger sized particles to provide a more uniform light. Larger particles are typically more efficient at converting light compared to smaller particles, but emit a less uniform light. In some embodiments, the phosphor can be provided in phosphor layer(s) 66 in a binder, and the phosphor can also have different concentrations or loading of phosphor materials in the binder. A typical concentration being in a range of 30-70% by weight. In one embodiment, the phosphor concentration is approximately 65% by weight, and is preferably uniformly dispersed throughout the remote phosphor. Phosphor layer(s) 66 can also have different regions with different conversion materials and different concentrations of conversion material.

Different materials can be used for the binder, with materials preferably being robust after curing and substantially transparent in the visible wavelength spectrum. Suitable materials include silicones, epoxies, glass, inorganic glass, dielectrics, BCB, polymides, polymers and hybrids thereof, with the preferred material being silicone because of its high transparency and reliability in high power LEDs. Suitable phenyl- and methyl-based silicones are commercially available from Dow® Chemical. The binder can be cured using many different curing methods depending on different factors such as the type of binder used. Different curing methods include but are not limited to heat, ultraviolet (UV), infrared (IR) or air curing. In some embodiments, the binder can comprise a polymeric material or plastic.

Phosphor layer(s) 66 can be applied using different processes including but not limited to spin coating, sputtering, printing, powder coating, electrophoretic deposition (EPD), electrostatic deposition, among others. As mentioned above, phosphor layer(s) 66 can be applied along with a binder material, but it is understood that a binder is not required. In still other embodiments, the phosphor layer 66 can be separately fabricated and then mounted to the carrier layer 64.

In one embodiment, a phosphor-binder mixture can be sprayed or dispersed over the carrier layer 64 with the binder then being cured to form the phosphor layer 66. In some of these embodiments the phosphor-binder mixture can be sprayed, poured or dispersed onto or over the a heated carrier layer 64 so that when the phosphor binder mixture contacts the carrier layer 64, heat from the carrier layer 64 spreads into and cures the binder. These processes can also include a solvent in the phosphor-binder mixture that can liquefy and lower the viscosity of the mixture making it more compatible with spraying. Many different solvents can be used including but not limited to toluene, benzene, zylene, or OS-20 commercially available from Dow Corning®, and different concentration of the solvent can be used. When the solvent-phosphor-binder mixture is sprayed or dispersed on the heated carrier layer 64 the heat from the carrier layer 64 evaporates the solvent, with the temperature of the carrier layer impacting how quickly the solvent is evaporated. The heat from the carrier layer 64 can also cure the binder in the mixture leaving a fixed phosphor layer on the carrier layer. The carrier layer 64 can be heated to many different temperatures depending on the materials being used and the desired solvent evaporation and binder curing speed. A suitable range of temperature is 90 to 150° C., but it is understood that other temperatures can also be used. Various deposition methods and systems are described in U.S. Patent Application Publication No. 2010/0155763, to Donofrio et al, entitled “Systems and Methods for Application of Optical Materials to Optical Elements,” and also assigned to Cree, Inc.

The phosphor layer 66 can have many different thicknesses depending at least partially on the concentration of phosphor material and the desired amount of light to be converted by the phosphor layer 66. Phosphor layers according to the present invention can be applied with concentration levels (phosphor loading) above 30%. Other embodiments can have concentration levels above 50%, while in still others the concentration level can be above 60%. In some embodiments the phosphor layer can have thicknesses in the range of 10-100 microns, while in other embodiments it can have thicknesses in the range of 40-50 microns.

The methods described above can be used to apply multiple layers of the same of different phosphor materials and different phosphor materials can be applied in different areas of the carrier layer using known techniques, such as masking processes. Other embodiments can comprise uniform and/or non-uniform distribution of phosphors in the phosphor carrier, such as with different phosphor layer thicknesses and/or different phosphor material concentrations along the carrier. There can be multiple areas of different types of phosphors that can emit the same or different colors of light, such as by having distinct regions/layers of different phosphors. Some of these arrangements can give the phosphor carrier a patterned appearance, with some of the patterns including but not limited to striped, dotted, crisscrossed, zigzagged or any combination of these. In still other embodiments, there can be multiple remotely separated phosphors (e.g. domes) that can have different types of phosphor materials. Each of these remote phosphors can have one or multiple phosphors that can be arranged in the many different ways described above.

The methods described above provide some thickness control for phosphor layer(s) 66, but for even greater thickness control the phosphor layer(s) can be ground using known methods to reduce the thickness of phosphor layer(s) or to even out the thickness over each entire layer. This grinding feature provides the added advantage of being able to produce lamps emitting within a single bin on the CIE chromaticity graph. Binning is generally known in the art and is intended to ensure that the LEDs or lamps provided in groups that emit light within an acceptable color range. The LEDs or lamps can be tested and sorted by color or brightness into different bins, generally referred to in the art as binning. Each bin typically contains LEDs or lamps from one color and brightness group and is typically identified by a bin code. White emitting LEDs or lamps can be sorted by chromaticity (color) and luminous flux (brightness). The thickness control of the phosphor layer provides greater control in producing lamps that emit light within a target bin by controlling the amount of light source light converted by each phosphor layer. Multiple carriers with the same thickness of each phosphor layer 66 can be provided. By using a light source 58 with substantially the same emission characteristics, lamps can be manufactured having nearly the same emission characteristics that in some instances can fall within a single bin. In some embodiments, the lamp emissions fall within a standard deviation from a point on a CIE diagram, and in some embodiments the standard deviation comprises less than a 10-step McAdams ellipse. In some embodiments the emission of the lamps falls within a 4-step McAdams ellipse centered at CIExy(0.313, 0.323).

The conversion element 62 can be mounted and bonded over the light source and/or the opening in the cavity 54 using different known methods or materials such as thermally conductive bonding materials or a thermal grease. Conventional thermally conductive grease can contain ceramic materials such as beryllium oxide and aluminum nitride or metal particles such colloidal silver. In other embodiments, the phosphor carrier can be mounted over the opening using thermal conductive devices such as clamping mechanisms, screws, or thermal adhesive hold conversion element 62 tightly to the heat sink structure to maximize thermal conductivity. In one embodiment a thermal grease layer is used having a thickness of approximately 100 μm and thermal conductivity of k=0.2 W/m-k. This arrangement provides an efficient thermally conductive path for dissipating heat from phosphor layer(s) 66. As mentioned above, different lamp embodiments can be provided without cavity and the phosphor carrier can be mounted in many different ways beyond over an opening to the cavity.

During operation of the lamp 50 phosphor conversion heating is concentrated in the phosphor layer 66, such as in the center of the phosphor layer 66 where the majority of LED light strikes and passes through the conversion element 62. The thermally conductive properties of the carrier layer 64 spreads this heat laterally toward the edges of the conversion element 62 as shown by first heat flow 70. There the heat passes through the thermal grease layer and into the heat sink structure 52 as shown by second heat flow 72 where it can efficiently dissipate into the ambient.

As discussed above, in the lamp 50 the platform 56 and the heat sink structure 52 can be thermally connected or coupled. This coupled arrangement results in the conversion element 62 and that light source 58 at least partially sharing a thermally conductive path for dissipating heat. Heat passing through the platform 56 from the light source 58 as shown by third heat flow 74 can also spread to the heat sink structure 52. Heat from the conversion element 62 flowing into the heat sink structure can also flow into the platform 56. In other embodiments, the conversion element 62 and the light source can have separate thermally conductive paths for dissipating heat, with these separate paths being referred to as “decoupled”.

It is understood that the conversion element and phosphor layer or layers can be arranged in many different ways beyond the embodiment shown in FIG. 4. The phosphor layer or layers can be on any surface on the inside or outside of the carrier layer or can be mixed in with the carrier layer. The phosphor carriers can also comprise scattering layers that can be included on or mixed in with the phosphor layer(s) or carrier layer. It is also understood that the phosphor and scattering layers can cover less than a surface of the carrier layer and in some embodiments the conversion layer and scattering layer can have different concentrations in different areas. It is also understood that the carrier can have different roughened or shaped surfaces to enhance emission through the carrier.

As discussed above, the diffuser 75 is arranged to disperse light from the conversion element and/or light source into the desired lamp emission pattern, and can have many different shapes and sizes. In some embodiments, the diffuser can also be provided in between the light source and the conversion element to disperse light primarily just from the light source. In still other embodiments, the diffuser can be arranged over the conversion element to mask the conversion element when the lamp is not emitting any light. The diffuser can have materials to give a substantially white appearance to give the bulb a white appearance when the lamp is not emitting.

Many different diffusers with different shapes and attributes can be used with lamp 50 as well as the lamps described below, such as those described in U.S. Provisional Patent Application No. 61/339,515, titled “LED Lamp With Remote Phosphor and Diffuser Configuration”, filed on Mar. 3, 2010, and assigned to the same assignee of the present invention and which is incorporated herein by reference. The diffuser can also take different shapes, including but not limited to generally asymmetric “squat” shapes as in U.S. patent application Ser. No. 12/901,405, titled “Non-uniform Diffuser to Scatter Light Into Uniform Emission Pattern,” filed on Oct. 8, 2010, assigned to the same assignee of the present invention, and incorporated herein by reference.

The lamps according to the present invention can comprise many different features beyond those described above. Referring again to FIG. 4, in those lamp embodiments having a cavity 54 can be filled with a transparent heat conductive material to further enhance heat dissipation for the lamp. The cavity conductive material could provide a secondary path for dissipating heat from the light source 58. Heat from the light source would still conduct through the platform 56, but could also pass through the cavity material to the heat sink structure 52. This would allow for lower operating temperature for the light source 58, but presents the danger of elevated operating temperature for the conversion element 62. This arrangement can be used in many different embodiments, but is particularly applicable to lamps having higher light source operating temperatures compared to that of the phosphor layer(s). This arrangement allows for the heat to be more efficiently spread from the light source in applications where additional heating of the conversion element can be tolerated.

As discussed above, different lamp embodiments according to the present invention can be arranged with many different types of light sources. In one embodiment, eight or nine LEDs can be used that are connected in series with two wires to a circuit board. The wires can then be connected to the power supply unit described above. In other embodiments, more or less than eight or nine LEDs can be used and as mentioned above, commercially available LEDs from Cree, Inc. can used including eight XLamp® XP-E LEDs or four XLamp® XP-G LEDs. Different single string LED circuits are described in U.S. patent application Ser. No. 12/566,195, to van de Ven et al., entitled “Color Control of Single String Light Emitting Devices Having Single String Color Control, and U.S. patent application Ser. No. 12/704,730 to van de Ven et al., entitled “Solid State Lighting Apparatus with Compensation Bypass Circuits and Methods of Operation Thereof”, both of which are assigned to the same assignee of the present invention and incorporated herein by reference.

FIG. 5 shows another embodiment of a lamp 100 according to the present invention, that may comprise an optical cavity similar to that discussed above (not shown), and a heat sink structure 102. Like the embodiments above, the lamp 100 can also be provided without a lamp cavity, with the LEDs mounted on a surface of the heat sink 102 or on a three dimensional or pedestal structures having different shapes. A planar, LED-based light source 104 is mounted to the platform 106, and a conversion element 108 is mounted over the light source 104, with the conversion element 108 having any of the features of those described above. In the embodiment shown, the conversion element 108 can be a generally globular shape, and may also comprise a thermally conductive transparent material and one or more distinct phosphor layers. It can be mounted to the heat sink or platform with a thermally conductive material or device as described above. If provided, the cavity can have reflective surfaces to enhance the emission efficiency as described above.

Light from the light source 104 passes through the conversion element 108 where a portion of it is converted to a different wavelength or wavelengths of light by the one or more distinct phosphor layers in the conversion element 108. In one embodiment, the light source 104 can comprise blue emitting LEDs and the conversion element 108 can comprise a distinct yellow phosphor layer and/or a distinct red phosphor layer as described above, that absorbs a portion of the blue light and re-emits yellow and/or red light. The lamp 100 emits a white light combination of LED light and phosphor layer(s) light. Like above, the light source 104 can also comprise many different LEDs emitting different colors of light and the conversion element 108 can comprise other distinct phosphor layers (each comprising one or a mixture of phosphor types) to generate light with the desired color temperature and rendering.

It is understood that the phosphor layers may be positioned on the outside surface of the carrier layer of the conversion element 108, may be positioned on the inside of the carrier layer, and/or one or more phosphor layers can be positioned on the inside of the carrier layer while one or more other phosphor layers can be positioned on the outside of the carrier layer. It is also understood that the distinct phosphor layers may be placed in an order such that the lower wavelength converter phosphor layer is closest to the light source, while the highest wavelength converter phosphor layer is further from the light source, with any intervening phosphor layers likewise ordered. Conversely, the distinct phosphor layers may be ordered such that the highest wavelength converter phosphor layer is closest to the light source, while the lowest wavelength converter phosphor layer is further from the light source and any intervening phosphor layers are similarly ordered.

The conversion element 108 may also comprise a bandpass filter, such as a dielectric mirror or antireflective coating, that may be included on the inside or outside of the conversion element globe/dome and/or on the inside or outside of the diffuser element globe/dome. Generally, the bandpass filter acts as a light reflector on one side, and a light transmitter on the other side. It does this by reflecting wavelengths of light that are greater than a specific value (such as >500 nm), and transmitting wavelengths of light that are lesser than a specific value (such as <500 nm). In one illustrative embodiment, the bandpass filter may reflect longer wavelengths such as yellow or anything greater than 500 nm, while transmitting shorter wavelengths such as blue or anything lesser than 500 nm. Ideally, it can be provided to ensure that the wavelength(s) of light being emitted from the LED(s) does not return to the light source, but is instead transmitted out and away from the light source so as to pass through the conversion element and diffuser element.

In one possible embodiment, the bandpass filter may be positioned on the conversion element inside one or more of the distinct phosphor layers. The bandpass filter may be designed to transmit blue, the color emitting from blue LEDs, and reflect longer wavelengths. However, it is understood that the bandpass filter can be designed to transmit any other desired color. In this possible embodiment, the light from the chips would pass through the filter and move on to the phosphor layer(s) and diffuser element. At least some of the light converted in the phosphor layer(s) may emit back toward the bandpass filter, which would then reflect those converted, higher wavelengths of light away from the light source and toward the user.

The bandpass filter may be comprised of many suitable materials known in the art. For example, materials that are commonly used for dielectric mirrors and antireflective coatings may be used. Such materials include, but are not limited to: MgF, TiO₂, SiO₂, ZrO₂, AlO₂, and Ta₂O₅.

The lamp 100 also comprises a shaped diffuser globe/dome 110 mounted over the light source 104 that includes diffusing or scattering particles such as those listed above. While the diffuser in this embodiment is shown as being outside the conversion element, it is understood that diffuser element may also be on the inside and/or incorporated within the conversion element. The scattering particles can be provided in a curable binder that is formed in the general shape of globe/dome. In the embodiment shown, the dome 110 is mounted to the heat sink structure 102. Different binder materials can be used as discussed above such as silicones, epoxies, glass, inorganic glass, dielectrics, BCB, polymides, plastics, polymers and hybrids thereof. In some embodiments, white scattering particles can be used within the globe/dome having a white color that hides the color of the phosphor layer(s) in the conversion element 108. This gives the overall lamp 100 a white appearance that is generally more visually acceptable or appealing to consumers than the color of the phosphor layer(s). In one embodiment the diffuser can include white titanium dioxide particles that can give the diffuser globe/dome 110 its overall white appearance.

The diffuser globe/dome 110 can provide the added advantage of distributing the light emitting from the light source in a more uniform pattern. As discussed above, light from the light source can be emitted in a generally Lambertian pattern, and the shape of the globe/dome 110 along with the scattering properties of the scattering particles causes light to emit from the dome in a more omnidirectional emission pattern. An engineered globe/dome can have scattering particles in different concentrations in different regions or can be shaped to a specific emission pattern.

In the United States, the ENERGY STAR® program, run jointly by the U.S. Environmental Protection Agency and the U.S. Department of Energy, promulgates a standard for integrated LED lamps; the measurement techniques for both color and angular uniformity are described in the ENERGY STAR® Program Requirements and are incorporated herein by reference. For a vertically oriented lamp, luminous intensity is measured in vertical planes 45 and 90 degrees from an initial plane. It shall not differ from the mean intensity by more than 20% for the entire 0-135 degree zone for the lamp, with zero defined as the top of the envelope. Additionally, 5% of the total flux from the lamp shall be in the 135-180 degree zone.

In some embodiments, including those described below, the diffuser globe/dome can be engineered so that the emission pattern from the lamp complies with the omnidirectional emission criteria of the ENERGY STAR® Program Requirements for Integral LED Lamps, amended Mar. 22, 2010, which is incorporated herein by reference. One requirement of this standard met by the lamps herein is that the emission uniformity must be within 20% of mean value from 0 to 135° viewing. Another is that greater than 5% of total flux from the lamp must be emitted in the 135-180° emission zone, with the measurements taken at 0, 45, 90° azimuthal angles. As mentioned above, the different lamp embodiments described herein can also comprise A-type (e.g. A19) retrofit LED bulbs that meet the DOE ENERGY STAR® standards. The present invention provides lamps that are efficient, reliable and cost effective. In some embodiments, the entire lamp can comprise five components that can be quickly and easily assembled.

Like the embodiments above, the lamp 100 can comprise a mounting mechanism 112 connected to the heat sink 102, of the type to fit in conventional electrical receptacles. In the embodiment shown, the lamp 100 includes a screw-threaded portion 112 for mounting to a standard Edison socket. Like the embodiments above, the lamp 100 can include a standard plug and the electrical receptacle can be a standard outlet, or can comprise a GU24 base unit, or it can be a clip and the electrical receptacle can be a receptacle which receives and retains the clip (e.g., as used in many fluorescent lights). The heat sink structure can also comprise an internal cavity or housing holding power supply or power conversion unit components as described above.

As mentioned above, the space between some of the features of the lamp 100 can be considered mixing chambers, with the space between the light source 104 and the conversion element 108 comprising a first light mixing chamber. The space between the conversion element 108 and the diffuser 110 can comprise a second light mixing chamber, with the mixing chamber promoting uniform color and intensity emission for the lamp. The same can apply to embodiments having differently shaped conversion elements and diffusers. In other embodiments, additional diffusers and/or conversion elements can be included forming additional mixing chambers, and the diffusers and/or conversion elements can be arranged in different orders.

FIGS. 6-8 depict various possible arrangements for conversion elements 108 according to the present invention that can be incorporated into the possible lamp devices. It is understood that the various possible conversion elements 108 are shown for illustrative purposes only, and are not meant to narrow the scope of the present invention and its plurality of possible embodiments. More than three distinct phosphor layers may be provided in any embodiment as desired, and may be positioned with respect to the carrier layer in any order as desired. In FIG. 6, a phosphor carrier layer 114 similar to that described in detail above is provided. The carrier layer 114 is provided in a globe/dome, although the shape can vary depending on the overall desired emission, light mixing, and light conversion characteristics of the lamp. The carrier layer 114 may be coated by one distinct phosphor layer 116, with the phosphor layer comprising red, yellow, or green phosphor. The layer 116 may also comprise two or more types of phosphors. The carrier layer 114 may be coated on its inside and/or outside surface by the phosphor layer 116.

In FIG. 7, a phosphor carrier layer 114 is again provided, but in this embodiment the layer 114 may be coated by two distinct phosphor layers 116, 118. The phosphor layers 116, 118 may coat the inside, outside, or both the inside and outside surfaces of the carrier layer 114, and may each comprise distinct red, yellow, or green layers. If the layers coat both the inside and outside of the carrier layer, one distinct phosphor layer may coat the inside surface of the carrier layer, while the other distinct phosphor layer may coat the outside surface of the carrier layer. One or both of the phosphor layers 116, 118 may also comprise mixtures of two or more types of phosphors in each layer. As a non-limiting example, in one possible embodiment for a lamp incorporating blue LEDs, it may be desirable to include distinct red and yellow phosphor layers, with the red layer closest to the light source. The red phosphor layer will absorb some of the blue light and convert it to red light, and the yellow phosphor layer will absorb some of the blue light and convert it to yellow light without generally also absorbing some of the red light. The resulting light emissions will produce a combination of red, yellow, and blue light that can emit from the lamp structure as white light. This arrangement can also help avoid double down-conversion of various wavelengths. However, double down-conversion may be desirable in some embodiments, in which case a different phosphor layer order and/or different phosphor layer compositions may alternatively be used.

In FIG. 8, a phosphor carrier layer 114 is provided again, but in this embodiment the layer 114 may be coated by three distinct phosphor layers 116, 117, 118. The phosphor layers 116, 117, 118 may coat the inside, outside, or both the inside and outside surfaces of the carrier layer 114, and may each comprise distinct red, yellow, or green layers and/or one, two or all three phosphor layers may also comprise mixtures of two or more phosphor types in each layer. Also, it is understood that one or more of the distinct phosphor layers may coat the inside surface of the carrier layer while one or more other distinct phosphor layers coat the outside surface of the carrier layer. As a non-limiting example, in one possible embodiment of a lamp structure incorporating blue LEDs, it may be desirable to include distinct red, yellow, and green phosphor layers, with the red layer closest to the light source and the green layer further from the light source. The red, yellow, and green layers will absorb some of the blue light from the LEDs and reemit it at respective red, yellow, and green wavelengths, with the yellow layer generally not absorbing the red light, and the green layer generally not absorbing the yellow light. The resulting light emissions will produce a combination of red, yellow, green, and blue light that can emit from the lamp structure as white light. This arrangement can also help avoid double down-conversion of various wavelengths. However, double down-conversion may be desirable in some embodiments, in which case a different phosphor layer order and/or different phosphor layer compositions may alternatively be used.

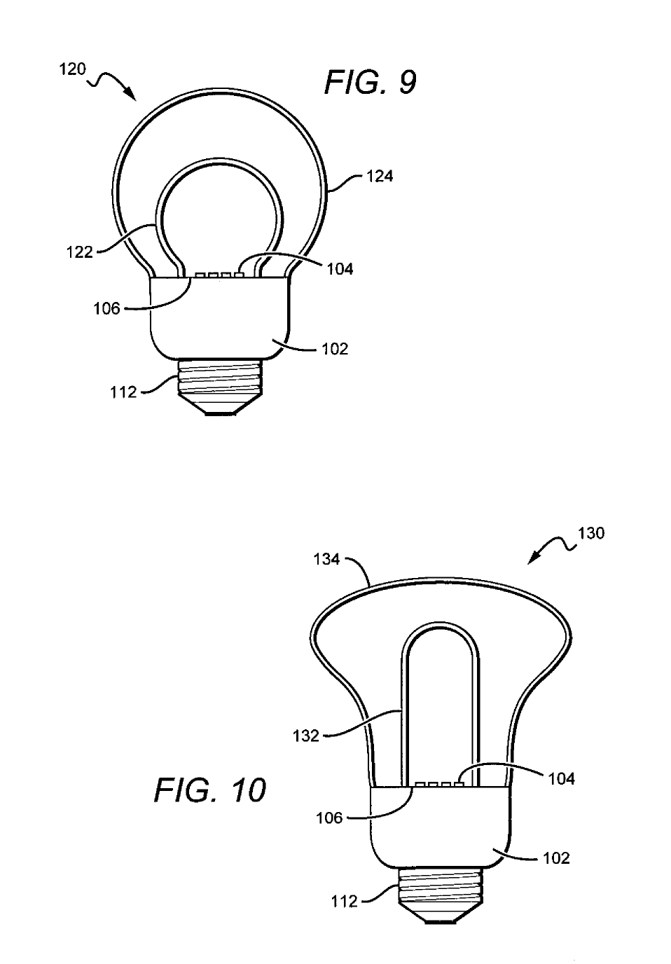

As discussed above, different lamp embodiments according to the present invention can have many different shapes, sizes and configurations. FIG. 9 shows another embodiment of a lamp 120 according to the present invention that is similar to the lamp 100 and similarly comprises a heat sink structure 102 with a light source 104 mounted to the platform 106. Like above, the heat sink structure 102 may also comprise an optical cavity. As above, the light sources can be provided on other structures beyond a heat sink structure. These can include planar surfaces or pedestals having the light source. A diffuser globe/dome element 122 is mounted over the light source 104. The diffuser element 122 can be made of the same materials as diffusers discussed above. The lamp 120 may also comprise a conversion element 124, but in this embodiment the conversion element 124 is disposed outside the diffuser 122. The conversion element 124 may comprise a carrier layer and one or more phosphor layers as described above. Putting the diffuser element 122 on the inside of the conversion element 124 may be desired in some applications where increased passes of emitted light and mixing of light from the light source may be desired before the light reaches the phosphor layer(s) on the conversion element (e.g. in scenarios where multiple color LEDs are used in the light source). However, this type of diffuser 122 placement may also equate to less light conversion because the light emitted from the light source will not have the opportunity to go through the phosphor layers prior to reaching the diffuser 122. In addition, more phosphor(s) may be required in this arrangement in part because the surface area of the conversion element is necessarily larger.

FIG. 10 shows another embodiment of a lamp 130 according to the present invention that is similar to the lamp 100 and similarly comprises a heat sink structure 102 with a light source 104 mounted to the platform 106. Like above, the heat sink structure 102 may also comprise an optical cavity. As above, the light sources can be provided on other structures beyond a heat sink structure. The lamp 130 may also comprise a conversion element 132 having a carrier and one or more distinct phosphor layers as described above, but in this embodiment the conversion element 132 is elongated and tube-like to provide different wavelength conversion characteristics. The lamp 130 may also comprise a diffuser element 134 disposed outside the conversion element 132, but in this embodiment the diffuser 134 is squashed or squat shaped to provide a different lamp emission pattern. The diffuser 134 may mask the color from the phosphor layer(s) in the conversion element 132.

It is understood that in other lamp embodiments the conversion element and diffuser can take many different shapes including different three-dimensional shapes or a planar configuration. As discussed above, when each phosphor layer absorbs and re-emits light, it is re-emitted in an isotropic fashion, such that the shape of the conversion element serves to convert and also disperse light from the light source. Like the diffusers described above, the different shapes can emit light in emission patterns having different characteristics that depend partially on the emission pattern of the light source. The diffuser can then be matched with the emission of the conversion element to provide the desired lamp emission pattern.

It is understood that the phosphor layer(s) can be on the carrier's inside or outside layer, mixed in with the carrier, or any combination of the three. In some embodiments, having the phosphor layer(s) on the outside surface may minimize emission losses. When emitter light is absorbed by the phosphor layer(s) it is emitted omnidirectionally and some of the light can emit backwards and be absorbed by the lamp elements such as the LEDs. The phosphor layers can also each have an index of refraction that is different from the carrier layer such that light emitting forward from each phosphor layer can be reflected back from the inside surface of the carrier. This light can also be lost due to absorption by the lamp elements. With each or at least some of the phosphor layers on the outside surface of the carrier, light emitted forward does not need to pass through the carrier and will not be lost to reflection. Light that is emitted back can encounter the top of the carrier where at least some of it can reflect back. This arrangement can result in a reduction of light from each phosphor layer that emits back into the carrier where it can be absorbed.

Each phosphor layer can be deposited using many of the same methods described above. In some instances the three-dimensional shape of the carrier may require additional steps or other processes to provide the necessary coverage. In the embodiments where a solvent-phosphor-binder mixture is sprayed and the carrier can be heated as described above and multiple spray nozzles may be needed to provide the desired coverage over the carrier, such as approximate uniform coverage. In other embodiments, fewer spray nozzles can be used while spinning the carrier to provide the desired coverage. Like above, the heat from the carrier can evaporate the solvent and helps cure the binder.

In still other embodiments, each phosphor layer can be formed through an emersion process whereby each phosphor layer can be formed on the inside or outside surface of the carrier, but is particularly applicable to forming on the inside surface. The carrier can be at least partially filled with, or otherwise brought into contact with, a phosphor or a phosphor mixture that adheres to the surface of the carrier. The individual phosphor or phosphor mixture can then be drained from the carrier leaving behind a layer of the phosphor or mixture on the surface, which can then be cured. In one embodiment, the mixture can comprise polyethylen oxide (PEO) and a phosphor. The carrier can be filled and then drained, leaving behind a layer of the PEO-phosphor mixture, which can then be heat cured. The PEO evaporates or is driven off by the heat leaving behind a phosphor layer. In some embodiments, a binder can be applied to further fix the phosphor layer, while in other embodiments the phosphor can remain without a binder.

Like processes used to coat planar carrier layers, these processes can be utilized in three-dimensional carriers to apply multiple, distinct phosphor layers that can have the same or different phosphor materials. The phosphor layers can also be applied both on the inside and outside of the carrier, and can have different types having different thickness in different regions of the carrier. In still other embodiments different processes can be used such as coating the carrier with a sheet of phosphor material that can be thermally formed to the carrier.

In lamps utilizing carriers according to the present invention, emitters can be arranged at the base of the carrier so that light from the emitters emits up and passes through the carrier. In some embodiments, the emitters can emit light in a generally Lambertian pattern, and the carrier can help disperse the light in a more uniform pattern.

As mentioned above, the conversion elements can comprise multiple conversion materials, such as yellow, green and red phosphors. These phosphors can provide the light components for the white light lamp emission. In different embodiments, however, these light components can be provided directly from LED chips instead of through phosphor conversion. These different arrangements can provide certain advantages, including but not limited to lamps that require lower operating power and can be less expensive by eliminating the need for certain phosphors. In other embodiments, some of these color components can be provided directly from the different color LED chips. For example, the red component of the emission can be provided directly from red emitting LEDs as described in U.S. Provisional Patent Application Ser. No. 61/424,670 to Yuan et at., titled “LED Lamp With Remote Phosphor and Diffuser Configuration Utilizing Red Emitters,” which is incorporated herein by reference.

Different lamp components can have many different shapes and can be arranged in many different ways. In particular, the heat sinks can be arranged in many different ways to meet the desired size, thermal management characteristics, and desired emission characteristics of the lamp. Moreover, the shapes of the conversion element and the diffuser element can impact the various emission characteristics of the lamp. U.S. Provisional Patent Application Ser. No. 61/435,759 describes various possible heat sink/thermal management configurations as well as conversion element and diffuser shapes and orientations, and is incorporated herein by reference. The 61/435,759 application also teaches: various mounting methods and mechanisms for components of lamps according to the present invention, various safety features, and various diffuser dome concentration regions, all of which are also incorporated herein by reference.

As discussed above and in the patent applications incorporated herein, diffuser domes according to the present invention can have different regions that scatter and transmit different amounts of light from the lamp light source to help produce the desired lamp emission pattern. In some embodiments, the different regions that scatter and transmit different amounts of light can be achieved by coating the diffuser dome with different amounts of diffusing materials at different regions. This can in turn modify the output beam intensity profile of a light source to provide improved emission characteristics as described above.

In some embodiments, the invention can rely on the combination of the diffuser element (i.e. diffuser dome) and diffuser coating scattering properties to produce the desired far-field intensity profile of the lamp. In different embodiments, the diffuser thickness and location may be dependent upon different factors such as the diffuser dome geometry, the light source arrangement, and the pattern of light emitting from the phosphor carrier.

It is also understood that the conversion element can have areas of differing concentrations of conversion material (i.e. phosphors). This can also assist in producing the desired emission profile as well as the desired light characteristics. In some embodiments, the conversion element can have increased conversion material at or around the top, although the increase can be in other areas. It is also understood that, like the diffuser coating, the conversion material can be applied in or on the carrier layer in any of the different internal and external coating combinations described above.

It is understood that lamps or bulbs according to the present invention can be arranged in many different ways beyond the embodiments described above. The embodiments above are discussed with reference to a remote phosphor but it is understood that alternative embodiments can comprise at least some LEDs with a conformal phosphor layer. This can be particularly applicable to lamps having light sources emitting different colors of light from different types of emitters. These embodiments can otherwise have some or all of the features described above.

Although the present invention has been described in detail with reference to certain preferred configurations thereof, other versions are possible. For example, different features or aspects of LED bulbs of the present invention are described in relation to various embodiments, but it should be understood that each of those features or aspects could be incorporated and used analogously in relation to any of the embodiments described herein as would be understood by one of ordinary skill in the art. Therefore, the spirit and scope of the invention should not be limited to the versions described above.

We claim:

1. A lighting device, comprising:
a solid state light source;
a diffuser element spaced apart from said light source; and
a wavelength conversion element spaced apart from said light source and apart from said diffuser element, wherein said wavelength conversion element comprises one or more distinct phosphor layers for converting the light emitted from said light source.

2. The lighting device of claim 1, emitting an emission pattern that complies with the ENERGY STAR® requirements.

3. The lighting device of claim 1, wherein said light source comprises one or more light emitting diodes (LEDs).

4. The lighting device of claim 3, wherein said light emitting diodes comprise blue LEDs.

5. The lighting device of claim 3, wherein said light emitting diodes comprise blue and red LEDs or any combination of LEDs.

6. The lighting device of claim 1, wherein each of said phosphor layers comprises a single color phosphor or single or multiple phosphor types.

7. The lighting device of claim 1, wherein the phosphor layers are ordered such that the lowest wavelength converter phosphor layer is closest to said light source and the highest wavelength converter phosphor layer is further from said light source.

8. The lighting device of claim 1, wherein the phosphor layers are ordered such that the highest wavelength converter phosphor layer is closest to said light source and the lowest wavelength converter phosphor layer is further from said light source.

9. The lighting device of claim 1, wherein the phosphor layer closest to said light source comprises a red phosphor, the phosphor layer furthest from said light source comprises a green phosphor, and the phosphor layer in between said red and green layers comprises a yellow phosphor.

10. The lighting device of claim 1, wherein said device is arranged to fit within the A19 envelope while emitting a substantially uniform emission pattern

11. The lighting device of claim 1, wherein said phosphor layers comprise distinct red, yellow, and green phosphor layers or any combination thereof.

12. The lighting device of claim 1, wherein said diffuser element comprises a globe at least partially coated with a diffusing material.

13. The lighting device of claim 1, wherein said diffuser element disperses light from said light source, from said wavelength conversion element, or from a combination of both said light source and said wavelength conversion element.

14. The lighting device of claim 1, wherein said wavelength conversion material and said diffuser element comprise a double-globe structure.

15. The lighting device of claim 1, further comprising a thermal management structure.

16. The lighting device of claim 1, wherein said distinct phosphor layers, composition of each phosphor layer, and/or the order of said phosphor layers reduces the amount of phosphor needed to convert light emitted from said light source compared to other remote phosphor applications.

17. The lighting device of claim 1, wherein said diffuser improves color uniformity and brightness and promotes a wider viewing angle.

18. The lighting device of claim 1, wherein said diffuser may be disposed outside said conversion element, inside said conversion element, or incorporated into said conversion element.

19. The lighting device of claim 1, further comprising a bandpass filter on said conversion element or said diffuser, said bandpass filter acting as a reflector to a specific range of wavelengths and a transmitter to a different specific range of wavelengths.

20. The lighting device of claim 1, wherein said wavelength conversion element is coated with a silicone layer on one side and one or more of said phosphor layers on another side.

21. The lighting device of claim 1, wherein said conversion element comprises a substantially transparent carrier material layer.

22. The lighting device of claim 1, wherein said diffuser element can be comprised of one or more of TiO₂, ZrO₂, BaSO₄, silica, or Al₂O₃.

23. The lighting device of claim 1, wherein said diffuser at least partially conceals the appearance of said wavelength conversion material when said lighting device is not illuminating.

24. The lighting device of claim 1, wherein said diffuser exhibits a white appearance when said lighting device is not illuminating.

25. The lighting device of claim 1, wherein said light source is mounted on a printed circuit board that is mounted to a heat sink, further comprising a protective layer to cover electrically conducting features on said PCB.

26. The lighting device of claim 1, wherein the light emitted from the diffuser has a spatial uniformity that is within 20% of a mean value within a range of viewing angles.

27. The lighting device of claim 26, wherein said range of viewing angles is 0 to 135°.

28. The lighting device of claim 25, having greater than 5% of total luminous flux in the 135 to 180° viewing angles.

29. A lighting device, comprising:
a solid state light source;
a diffuser element over said light source; and
a wavelength conversion element over said light source, wherein said wavelength conversion element comprises one or more distinct phosphor layers for converting the light emitted from said light source.

30. The lighting device of claim 29, arranged to fit an A19 size envelope.

31. The lighting device of claim 29, wherein said light source comprises one or more light emitting diodes (LEDs), comprising any desired color or color combination of LEDs.

32. The lighting device of claim 29, wherein said phosphor layers comprise distinct red, yellow, or green phosphor layers or any combination thereof.

33. The lighting device of claim 29, wherein any of said phosphor layers may comprise one or more phosphor types in any desired combination.

34. The lighting device of claim 29, wherein the phosphor layers are ordered such that the lowest wavelength converter phosphor layer is closest to said light source and the highest wavelength converter phosphor layer is further from said light source.

35. The lighting device of claim 29, wherein the phosphor layers are ordered such that the highest wavelength converter phosphor layer is closest to said light source and the lowest wavelength converter phosphor layer is further from said light source.

36. The lighting device of claim 29, wherein the phosphor layer closest to said light source comprises a red phosphor, the phosphor layer furthest from said light source comprises a green phosphor, and the phosphor layer in between said red and green layers comprises a yellow phosphor.

37. The lighting device of claim 29, wherein said wavelength conversion material and said diffuser element comprise a double-globe structure.

38. The lighting device of claim 29, further comprising a thermal management structure.

39. The lighting device of claim 29, wherein said distinct phosphor layers, composition of each phosphor layer, and/or the order of said phosphor layers reduces the amount of phosphor needed to convert light emitted from said light source compared to other remote phosphor applications.

40. The lighting device of claim 29, wherein said diffuser may be disposed outside said conversion element, inside said conversion element, or incorporated into said conversion element.

41. The lighting device of claim 29, further comprising a bandpass filter on said conversion element or said diffuser, said bandpass filter coating acting as a reflector to a specific range of wavelengths and a transmitter to a different specific range of wavelengths.

42. A solid state lamp, comprising:
a solid state light source;
a diffuser element over and spaced apart from said light source; and
a wavelength conversion element over and spaced apart from said light source and over and spaced apart from said diffuser element, wherein said wavelength conversion element comprises one or more distinct phosphor layers for converting the light emitted from said light source;
wherein said diffuser element and said wavelength conversion element provide a double-globe structure.

43. The lamp of claim 42, wherein said distinct phosphor layers, composition of each phosphor layer, and/or the order of said phosphor layers reduces the amount of phosphor needed to convert light emitted from said light source compared to other remote phosphor applications.

44. The lamp of claim 42, wherein each of said phosphor layers may comprise a distinct color and any of said phosphor layers may comprise one or more phosphor types arranged in any suitable combination.

45. A solid state lamp, comprising:
a solid state light source;
a diffuser element over and spaced apart from said light source; and
a wavelength conversion element over and spaced apart from said light source, wherein said wavelength conversion element comprises one or more distinct phosphor layers for converting the light emitted from said light source;
wherein said diffuser element is over and spaced apart from said wavelength conversion element, said diffuser element and wavelength conversion element providing a double-globe structure.

46. The lamp of claim 45, wherein said diffuser element converts more light than a similar diffuser element disposed inside a conversion element.

47. The lamp of claim 45, wherein said distinct phosphor layers, composition of each phosphor layer, and/or the order of said phosphor layers reduces the amount of phosphor needed to convert light emitted from said light source compared to other remote phosphor applications.

48. The lamp of claim 45, wherein each of said phosphor layers may comprise a distinct color and any of said phosphor layers may comprise one or more phosphor types arranged in any suitable combination.
